(19) United States
(12) Patent Application Publication
(10) Pub. No.: US 2015/0144255 A1
(43) Pub. Date: May 28, 2015

(54) METHOD OF FORMING A TOUCH PANEL

(71) Applicant: HengHao Technology Co. LTD, Taoyuan County (TW)

(72) Inventor: YEN-CHUN PENG, Taoyuan County (TW)

(73) Assignee: HengHao Technology Co. LTD, Taoyuan County (TW)

(21) Appl. No.: 14/099,946

(22) Filed: Dec. 7, 2013

(30) Foreign Application Priority Data
Nov. 26, 2013 (TW) 102143103

(51) Int. Cl. H05K 3/36; B32B 37/12; B32B 37/14

(52) U.S. Cl. CPC H05K 3/368; B32B 37/14; B32B 37/12; H05K 2203/061; B32B 2307/202; B32B 2307/206; B32B 2307/412; B32B 2313/04; B32B 2311/00
USPC 156/182

(57) ABSTRACT

A method of forming a touch panel includes bonding a transparent conductive transfer film (TCTF) with a cover layer, followed by patterning the TCTF into a first electrode layer. A second electrode layer is formed on a top surface of a transparent substrate, followed by forming an adhesive layer above the second electrode layer. Finally, a bottom surface of the first electrode layer is bonded with a top surface of the adhesive layer, thereby resulting in the touch panel.

### BACKGROUND OF THE INVENTION

1. Field of the Invention

The disclosure generally relates to a method of forming a touch panel, and more particularly to a method of directly bonding an electrode layer with a cover layer.

2. Description of Related Art

Touch screens adopting sensing technology and display technology have been widely employed for input/output functionality in electronic devices such as portable or hand-held electronic devices.

A capacitor-based touch panel is a commonly used touch panel that utilizes capacitive coupling to detect touch position. Specifically, changes in capacitance corresponding to the touch position are detected when a finger touches a surface of the touch panel.

Transparent conductive material, such as indium tin oxide (ITO), is commonly used to form a receive electrode for a conventional touch panel. The receive electrode is formed below a cover glass by adopting a specific technique such as film coating, which disadvantageously results in a complex, time-consuming and low-yield process.

For the foregoing reasons, a need has thus arisen to propose a novel method of forming a touch panel in a simple, fast and high-yield manner.

### SUMMARY OF THE INVENTION

In view of the foregoing, it is an object of the embodiment of the present invention to provide a method of forming a touch panel, in which a receive electrode layer is directly bonded with a cover layer, thereby simplifying and accelerating the formation of the touch panel and increasing yield.

According to one embodiment, a cover layer is provided; a transparent conductive transfer film (TCTF) is bonded with the cover layer; and the TCTF is patterned to form a first electrode layer. On the other hand, a transparent substrate is provided; a second electrode layer is formed on a top surface of the transparent substrate; and an adhesive layer is formed above the second electrode layer. Finally, a bottom surface of the first electrode layer is bonded with a top surface of the adhesive layer, thereby resulting in the touch panel.

### BRIEF DESCRIPTION OF THE DRAWINGS

FIG. 1A to FIG. 1C show cross-sectional views illustrating a process of forming a touch panel according to a first embodiment of the present invention; and

FIG. 2A to FIG. 2C show cross-sectional views illustrating a process of forming a touch panel according to a second embodiment of the present invention.

### DETAILED DESCRIPTION OF THE INVENTION

In the disclosure, a direction of “above” or “top” points to a touch position, while the directional terms “below” and “bottom” point against the touch position.

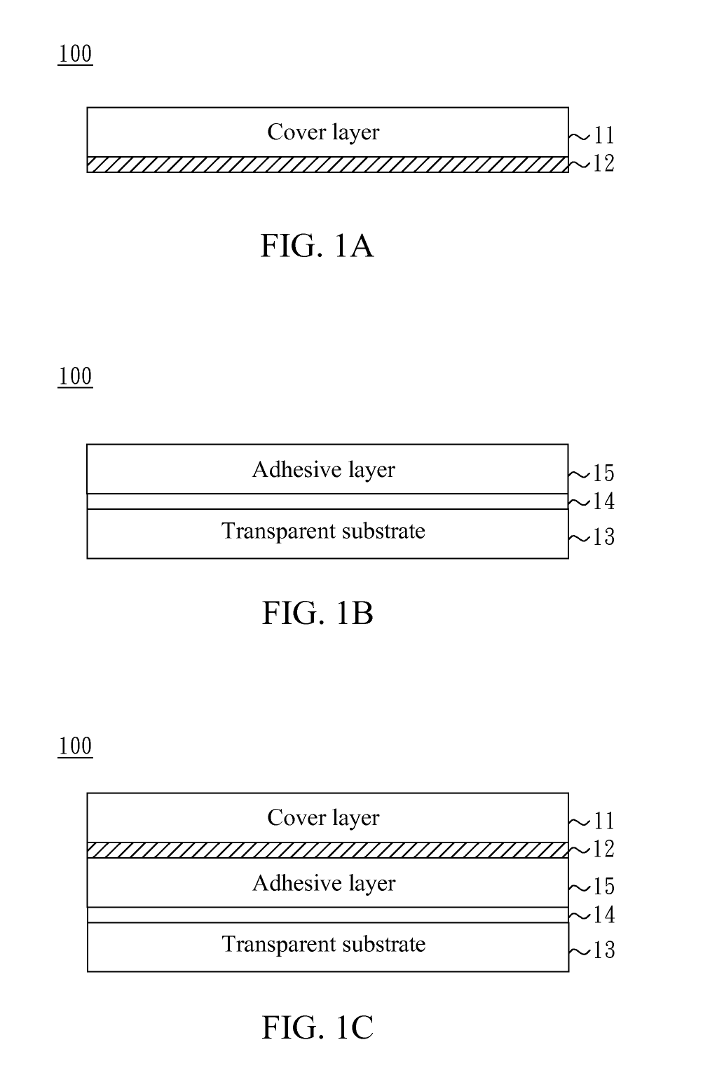

Referring more particularly to the drawings, FIGS. 1A to 1C are cross-sectional views corresponding to a process of forming a touch panel 100 according to a first embodiment of the present invention. As shown in FIG. 1A, a cover layer 11 is first provided. The cover layer 11 may be a two-dimensional cover layer with a planar surface, or a three-dimensional cover layer with a curved surface. The cover layer 11 may comprise flexible or rigid insulating material with high light-transmittance such as, but not necessarily, glass, Polycarbonate (PC), Polyethylene terephthalate (PET), Polymethyl methacrylate (PMMA) or Cyclic olefin copolymer (COC).

According to one aspect of the embodiment, a transparent conductive transfer film (TCTF) is directly bonded with a bottom surface of the cover layer 11. The TCTF is then patterned to make a first electrode layer 12, such as a receive electrode (commonly called Rx electrode).

The TCTF may comprise non-transparent conductive material such as metal nanowires (e.g., silver nanowires or copper nanowires) or metal nanonets (e.g., silver nanonets or copper nanonets). The metal nanowires or nanonets have diameters on the order of nanometers (i.e., a few nanometers to hundreds of nanometers), and may be fixed via a plastic material (e.g., resin). Due to the fineness and inability of the metal nanowires/nanonets to be observed by human eyes, the first electrode layer 12 made of such metal nanowires/nanonets has a high light-transmittance. Alternatively, the non-transparent conductive material may include Carbon nanotubes or Graphene nano-structures.

The first electrode layer 12 may further include a photosensitive material, through which electrodes with a required pattern may be directly formed via an exposure development process without using photoresist. The TCTF may itself have adhesiveness, in which case the TCTF may be bonded with the cover layer 11 without an extra adhesive layer.

As described before, transparent conductive material, such as indium tin oxide (ITO), is commonly used to form a receive electrode for a conventional touch panel. The receive electrode is formed below a cover glass by adopting a complex process such as film coating. In the embodiment, on the contrary, the first electrode layer 12 may be adhesively bonded with a bottom surface of the cover layer 11 and then patterned. Therefore, the process may be simplified and accelerated, and the yield may be substantially increased.

As shown in FIG. 1B, a transparent substrate 13 is provided. The transparent substrate 13 may comprise insulating material such as, but not necessarily, glass, Polycarbonate (PC), Polyethylene terephthalate (PET), Polyethylene (PE), Poly vinyl chloride (PVC), Poly propylene (PP), Poly styrene (PS), Polymethyl methacrylate (PMMA) or Cyclic olefin copolymer (COC).

Subsequently, a second electrode layer 14, such as a transmit electrode (commonly called Tx electrode) is formed on a top surface of the transparent substrate 13. The second electrode layer 14 of the embodiment may comprise transparent conductive material such as, but not necessarily, indium tin oxide (ITO), indium zinc oxide (IZO), Al-doped ZnO (AZO) or antimony tin oxide (ATO). Alternatively, the second electrode layer 14 of the embodiment may constitute non-transparent material such as metal nanowires (e.g., silver nanowires or copper nanowires) or metal nanonets (e.g., silver nanonets or copper nanonets).

An adhesive layer 15 may be formed above the second electrode layer 14. The adhesive layer 15 may comprise (solid) optically-clear adhesive (OCA) or (liquid) optically-clear resin (OCR).

The process demonstrated in FIG. 1B may be performed after, before or concurrently with the process demonstrated in FIG. 1A.

Finally, the structure of FIG. 1A and the structure of FIG. 1B are stacked. Specifically, a bottom surface of the first electrode layer 12 is bonded with a top surface of the adhesive layer 15, thereby resulting in the touch panel 100 shown in FIG. 1C.

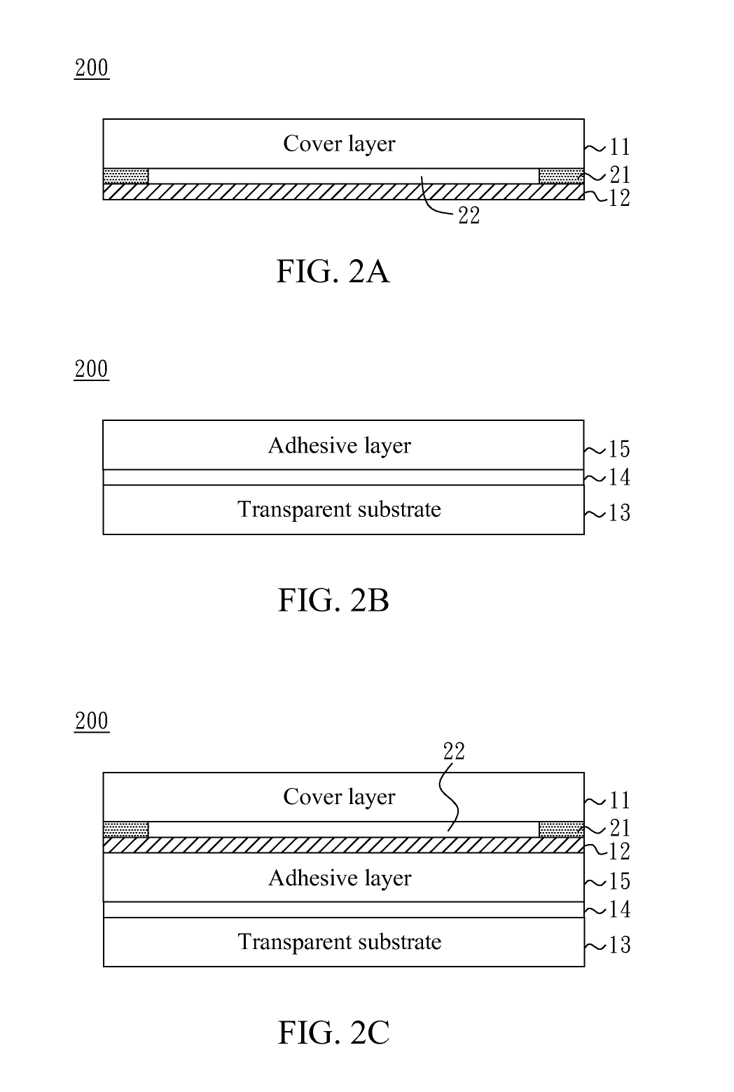

FIG. 2A to FIG. 2C show cross-sectional views illustrating a process of forming a touch panel 200 according to a second embodiment of the present invention. Same components as the first embodiment are denoted with same numerals, and their descriptions are omitted for brevity.

As shown in FIG. 2A, a cover layer 11 is first provided. A portion of a bottom surface of the cover layer 11 (e.g., area outside an active area) may be covered with black matrix (BM) 21. In order to compensate the step between the black matrix 21 and the exposed cover layer 11, a filling layer 22 is formed, in the embodiment, on area outside the black matrix 21, such that a bottom surface of the filling layer 22 and a bottom surface of the black matrix 21 are substantially on a same plane. The filling layer 22 of the embodiment may comprise transparent conductive material.

According to one aspect of the embodiment, a transparent conductive transfer film (TCTF) is directly bonded with the bottom surface of the filling layer 22 and the bottom of the black matrix 21. The TCTF is then patterned to form a first electrode layer 12, such as a receive electrode.

As shown in FIG. 2B, a transparent substrate 13 is provided. Subsequently, a second electrode layer 14, such as a transmit electrode is formed on a top surface of the transparent substrate 13. An adhesive layer 15 may then be formed above the second electrode layer 14.

Finally, the structure of FIG. 2A and the structure of FIG. 2B are stacked. Specifically, a bottom surface of the first electrode layer 12 is bonded with a top surface of the adhesive layer 15, thereby resulting in the touch panel 200 shown in FIG. 2C.

Although specific embodiments have been illustrated and described, it will be appreciated by those skilled in the art that various modifications may be made without departing from the scope of the present invention, which is intended to be limited solely by the appended claims.

What is claimed is:

1. A method of forming a touch panel, comprising:
providing a cover layer;
bonding a transparent conductive transfer film (TCTF) with the cover layer;
patterning the TCTF into a first electrode layer;
providing a transparent substrate;
forming a second electrode layer on a top surface of the transparent substrate;
forming an adhesive layer above the second electrode layer; and
bonding a bottom surface of the first electrode layer with a top surface of the adhesive layer, thereby resulting in the touch panel.

2. The method of claim 1, wherein the cover layer comprises transparent insulating material.

3. The method of claim 1, wherein the TCTF comprises non-transparent conductive material.

4. The method of claim 3, wherein the non-transparent conductive material comprises metal nanowires or metal nanonets.

5. The method of claim 3, wherein the non-transparent conductive material comprises Carbon nanotubes or Graphene nano-structures.

6. The method of claim 1, wherein the TCTF comprises photosensitive material.

7. The method of claim 1, wherein the second electrode layer comprises transparent conductive material.

8. The method of claim 1, wherein the second electrode layer comprises non-transparent conductive material.

9. The method of claim 1, wherein the TCTF is directly bonded with a bottom surface of the cover layer.

10. The method of claim 1, further comprising a step of forming a black matrix covering a portion of a bottom surface of the cover layer.

11. The method of claim 10, further comprising a step of forming a filling layer on the bottom surface of the cover layer outside the black matrix.

12. The method of claim 11, wherein the TCTF is directly bonded with the bottom surface of the cover layer and a bottom surface of the black matrix.
